(19) United States
(12) Patent Application Publication
(10) Pub. No.: US 2010/0272141 A1
(43) Pub. Date: Oct. 28, 2010

(54) NITRIDE SEMICONDUCTOR FREESTANDING SUBSTRATE AND MANUFACTURING METHOD OF THE SAME, AND LASER DIODE

(75) Inventor: Hajime FUJIKURA, Tokyo (JP)

Correspondence Address: Fleit Gibbons Gutman Bongini & Bianco PL, 21355 EAST DIXIE HIGHWAY, SUITE 115, MIAMI, FL, 33180, US

(73) Assignee: HITACHI CABLE, LTD., Tokyo (JP)

(21) Appl. No.: 12/571,527

(22) Filed: Oct. 1, 2009

(30) Foreign Application Priority Data
Apr. 23, 2009 (JP) 2009-105029

(51) Int. Cl. H01S 5/30; H01L 29/12; C30B 25/02

(52) U.S. Cl. 372/45.01; 257/613; 117/102; 257/E29.068

(57) ABSTRACT

There is provided a nitride semiconductor freestanding substrate, with a dislocation density set to be 4×10⁶/cm² or less in a surface of the nitride semiconductor freestanding substrate, having an in-surface variation of directions of crystal axes along the substrate surface at each point on the substrate surface, with this variation of the directions of the crystal axes along the substrate surface set to be in a range of ±0.2° or less.

### BACKGROUND

1. Technical Field

The present invention relates to a nitride semiconductor substrate used in manufacturing a light emitting diode and a laser diode of blue color, green color, and ultraviolet, or an electronic device, etc, and a manufacturing method of the same, and relates to a laser diode manufactured by using this nitride semiconductor freestanding substrate.

2. Description of Related Art

Nitride semiconductors such as gallium nitride (GaN), aluminum gallium nitride (AlGaN), and indium gallium nitride (InGaN) are focused as light emitting device materials covering from ultraviolet to green color, and as electronic device materials with high temperature operation and high output operation.

Conventionally, in a semiconductor other than a nitride semiconductor, in many cases, various devices are realized and put to practical use by preparing a freestanding substrate made of a single crystal, being a homogeneous semiconductor, and forming thereon a device structure by various crystal growth methods.

Meanwhile, in the nitride semiconductor, it is technically difficult to obtain a freestanding substrate of a single crystal made of nitride semiconductor such as GaN and AlN, and therefore there is no other choice but to use a heterogeneous substrate (a foreign substrate) such as sapphire and SiC. In this case, high dense defects (dislocation) are generated in a grown layer of the nitride semiconductor on the heterogeneous substrate, and this is a great factor of inhibiting an improvement of a device characteristic. If a typical example is given, a service life of a semiconductor laser (laser diode) greatly depends on a dislocation density in a crystal, and therefore in an element formed by a crystal growth on the heterogeneous substrate, it is difficult to obtain a practical element service life.

However, in recent years, the freestanding substrate of a single crystal with low defect density made of GaN and AlN has been supplied by various methods, and the semiconductor laser using the nitride semiconductor has been put to practical use.

Various methods are proposed, as a manufacturing method of the freestanding substrate of a nitride semiconductor single crystal. Typically, a method of growing a GaN layer thick on a seed substrate by a Hydride Vapor Phase Epitaxy Method (HVPE method) and removing the seed substrate during growth or after growth, and an Na flux method of mixing Ga metal in molten Na and separating out GaN on a seed crystal under a pressurized state of nitrogen, and an ammonothermal method of dissolving Ga or GaN into ammonia and separating out GaN on the seed crystal at high temperature and under high pressure, are known.

Among these methods, several methods based on the HVPE method achieve successful outcome at present, and a GaN freestanding substrate having a large area (2 inch diameter) produced by these methods are already commercially available. Typically, a method of depositing Ti on the surface of a GaN thin film on a sapphire substrate, then applying heat treatment thereto to thereby form a void structure and growing thereon the GaN layer thick by the HVPE method, and separating the sapphire substrate from the aforementioned void structure portion (Void-Assisted Separation Method:VAS method, see document 1), or a method of growing the GaN layer thick on the GaAs substrate by the HVPE method, with the surface partially covered with an insulating mask, and thereafter removing the GaAs substrate (Dislocation Elimination by the Epi-growth with Inverted-Pyramidal Pits Method:DEEP method, see document 2), are known.

(Document 1) Yuichi Oshima et al., Japanese Journal of Applied Physics, Vol. 42 (2003), PP.L1-L3.

(Document 2) Kensaku Motoki et al., Journal of Crystal Growth, Vol. 305 (2007), pp. 377-383.

However, when laser is manufactured by using the aforementioned nitride semiconductor freestanding substrate, production yield of the nitride semiconductor laser is 10% or less and is extremely poor. When it is taken into consideration that the production yield of 50% or more can be easily obtained in a case of a conventional GaAs-based laser, there are some problems in the present nitride semiconductor freestanding substrate.

### SUMMARY OF THE INVENTION

An object of the present invention is to provide a nitride semiconductor freestanding substrate capable of manufacturing, for example, a laser diode with high production yield and a manufacturing method of the same, and a laser diode using this freestanding substrate, with high production yield.

According to an aspect of the present invention, there is provided a nitride semiconductor freestanding substrate, with a dislocation density set to be 4×10⁶/cm² or less in a surface of the nitride semiconductor freestanding substrate, having an in-surface variation of directions of crystal axes along the substrate surface at each point on the substrate surface, with this variation of the directions of the crystal axes along the substrate surface set to be in a range of ±0.2° or less.

In the aforementioned nitride semiconductor freestanding substrate, preferably the nitride semiconductor freestanding substrate is has a wurtzite structure, and the substrate surface is C-face, M-face, and A-face, or a high index face. Note that here, the high index face means a face, with an absolute value of any one of h, k, l and m set to be 2 or more, when an index face is expressed by (hklm) (wherein, any one of h, k, l, m is an integer). As examples of the high index face, for example, (11-22) face and (12-32) face can be given.

Further, the surface of the nitride semiconductor freestanding substrate may also be an inclined surface (vicinal surface) inclined from the C-face, M-face, A-face in a range of 5° or less, or may be an inclined surface which is inclined in a range of 5° or less from the high index face, being the intermediate of the C-face, M-face, and A-face. This is because by forming the surface of the freestanding substrate into the inclined surface (vicinal surface) inclined at minute angles from an accurate crystal face, flatness of a crystal layer grown on the surface of the freestanding substrate can be improved.

Moreover, in the nitride semiconductor freestanding substrate, the nitride semiconductor freestanding substrate may be the nitride semiconductor having a zinc blende structure. In a case of the zinc blende structure, the surface of the nitride semiconductor freestanding substrate is preferably formed into (001) face, (111) A-face, (111) B-face, or the high index face between these faces (for example, (113) A-face and (114) B-face), or is preferably the inclined surface inclined from these faces in a range of 5° or less.

In the nitride semiconductor freestanding substrate having in-surface variation of ±0.2 or less of the directions of the crystal axes along the substrate surface at each point in the surface of the substrate, the in-surface variation of the directions of the crystal axes along a vertical line on the substrate surface is also preferably set to be in a range of ±0.2° or less.

Further, in the nitride semiconductor freestanding substrate, a film thickness distribution of the nitride semiconductor freestanding substrate in as-grown state is preferably set to be ±2% or less.

According to another aspect of the present invention, there is provided the laser diode, with an epitaxial layer of a laser diode structure formed so as to be laminated on the nitride semiconductor freestanding substrate. By using the nitride semiconductor freestanding substrate, with directions of the crystal axes aligned, the laser diode can be obtained with high production yield.

According to another aspect of the present invention, there is provided a manufacturing method of the nitride semiconductor freestanding substrate, comprising the steps of:

growing a nitride semiconductor layer, becoming a nitride semiconductor freestanding substrate, on a substrate for growth by supplying gas containing source gas, using a hydride vapor phase epitaxy method or a metal-organic vapor phase epitaxy method; and

manufacturing the nitride semiconductor freestanding substrate from the nitride semiconductor layer obtained by removing the substrate for growth.

wherein in the step of growing the nitride semiconductor layer, a gas flow speed of the gas containing the source gas in an area for growing the nitride semiconductor layer on the substrate for growth is set to be 1 m/s or more, and a distance from a gas jet hole for jetting the gas containing the source gas for forming the nitride semiconductor layer, to the area for growing the nitride semiconductor layer is set to be 50 cm or more, to thereby grow the nitride semiconductor layer with a dislocation density set to be 4×10⁶/cm² or less.

In the manufacturing method of the nitride semiconductor freestanding substrate, a growing rate distribution in a surface of the nitride semiconductor layer is preferably set to be ±2% or less.

### BRIEF DESCRIPTION OF THE DRAWINGS

FIG. 1 is a perspective view explaining a variation of directions of crystal axes of a nitride semiconductor substrate.

FIG. 2 is a schematic vertical sectional view of an HVPE apparatus used in an embodiment and an example of a manufacturing method of the nitride semiconductor freestanding substrate according to the present invention.

FIG. 3A, FIG. 3B, and FIG. 3C are schematic sectional views showing one step of the manufacturing steps of a GaN freestanding substrate according to an example of the present invention.

FIG. 4 is a graph showing a relation between a dislocation density of the GaN freestanding substrate and a variation of directions of crystal axes along a substrate surface.

FIG. 5 is a graph showing the relation between the dislocation density of the GaN freestanding substrate and the variation of the directions of the crystal axes along a vertical line on the substrate surface.

FIG. 6 is a sectional view showing an example of a laser diode in which an epitaxial layer of a laser structure is formed on the GaN freestanding substrate.

FIG. 7 is a graph showing the relation among a distance from a gas jet hole to a substrate, a gas flow speed, and a film thickness distribution in the surface of the substrate, in a GaN growth using an HVPE apparatus of FIG. 2.

FIG. 8 is a graph showing the relation among the distance from the gas jet hole to the substrate, the gas flow speed, and the variation of the directions of the crystal axes along the substrate surface, in the GaN growth using the HVPE apparatus of FIG. 2.

### DESCRIPTION OF PREFERRED EMBODIMENTS OF THE INVENTION

A nitride semiconductor freestanding substrate according to an embodiment of the present invention and a manufacturing method of the same, and a laser diode will be described hereinafter.

### (Variation of Crystal Axes of the Nitride Semiconductor Freestanding Substrate and its Problem)

As a result of examining by the inventors of the present invention the nitride semiconductor freestanding substrate in detail, which is manufactured by the aforementioned conventional method, it is found that at least one of a variation of directions of crystal axes along a substrate surface (directions of the crystal axes approximately parallel to the substrate surface) and a variation of directions of crystal axes along a vertical line on the substrate surface (directions of the crystal axes approximately vertical to the substrate surface) is a variation considered to be problematic in improving device characteristics. Note that the substrate surface means a growth surface, being a main face of the substrate, and in-surface of the substrate means the in-surface in the growth surface of the substrate.

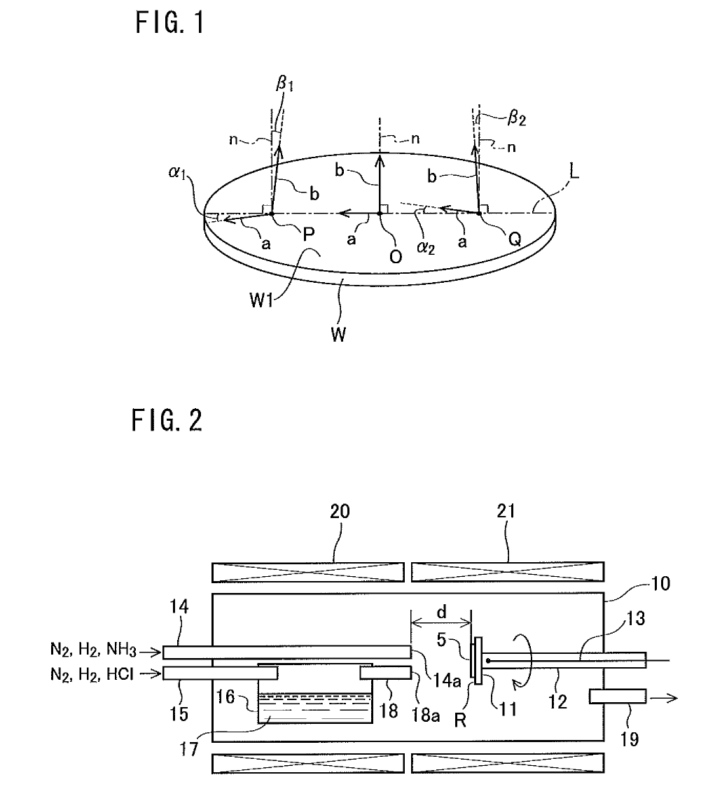

FIG. 1 shows a typical example of the variation of the directions of the crystal axes of the nitride semiconductor freestanding substrate. In FIG. 1, the directions of specific crystal axes approximately parallel to substrate surface W1, along the substrate surface W1 of a nitride semiconductor freestanding substrate W are set as “a”, and the directions of specific crystal axes approximately vertical to the substrate surface W1, along a vertical line (normal line) “n” of the substrate surface W1 are set as “b”. For the purpose of convenience, FIG. 1 shows the variation of the directions of the crystal axes at three points of point O, point P, and point Q. The point O is a center of the substrate surface W1, and point P and point Q are on straight line L along the direction “a” of the crystal axis at point O.

At point P set away from point O of the center, direction “a” of the crystal axis parallel to the substrate surface W1 is deviated in a counter clockwise direction by angle α1 (angle +α1 when the angle in the counter clockwise direction is set to be positive), from the direction “a” of the crystal axis in the direction parallel to the substrate surface W1 at point O. Also, at point Q set away from point O of the center, direction “a” of the crystal axis in a direction parallel to the substrate surface W1 is deviated from the direction “a” of the crystal axis in the direction parallel to the substrate surface W1 at point O, by angle α2 in a clockwise direction (angle −α2, because the deviating direction is the clockwise direction).

The variation of the directions “a” of the crystal axes in the direction parallel to the substrate surface W1 is the variation of the crystal axes in which when it is taken into consideration that a tangential directions at each point on a certain line on the substrate surface W1 are directions “a” of the crystal axes in the direction parallel to the substrate surface W1 (line formed so that the tangential directions at each point on this line coincide with directions of velocity vectors like a streamline), this line is not a straight line but a curved line.

Further, in the example shown in FIG. 1, direction “b” of the crystal axis in a direction vertical to the substrate surface W1 at point O of the center, approximately coincides with vertical line “n” on the substrate surface W1, and at point P, the direction “b” of the crystal axis in the direction vertical to the substrate surface W1 is deviated toward the clockwise direction from the vertical line “n” on the substrate surface W1, by angle β1 (angle −β1, when the angle in the clockwise direction is set to be negative). Moreover, at point Q, the direction “b” of the crystal axis in the direction vertical to the substrate surface W1 is deviated in the counter clockwise direction from the vertical line “n” on the substrate surface W1, by angle β₂ (angel +β₂, because the deviating direction is the counter clockwise direction).

As shown in FIG. 1, the directions of the crystal axes at each point in the surface of the substrate of the nitride semiconductor freestanding substrate manufactured by the conventional method, are not uniformly aligned, and there is a certain degree (about ±0.5°) of variation in at least one of the direction “a” of the crystal axis along the substrate surface, and the direction “b” of the crystal axis along the vertical line on the substrate surface. This variation of the directions of the crystal axes is considered to invite lowering of the production yield in manufacturing devices and inhibit improvement of the device characteristics.

For example, when the laser diode is manufactured, a reflecting surface of a resonator required for laser oscillation is formed by cleavage surfaces of both ends of a laser diode chip. In a conventional GaAs-based or InP-based laser diode, the cleavage surfaces, being crystal faces, are set in an extremely precise parallel relation, and it is confirmed that such a laser diode is actually operated as an ideal resonator. However, when the freestanding substrate, with directions “a” and “b” of the crystal axes as described above are not aligned, is used in manufacturing the laser diode of the nitride semiconductor, there is no guarantee that the cleavage surfaces of both ends of the laser chip are parallel, and variation occurs in parallelism of the cleavage surfaces. Such a variation is considered to be a cause of extremely low production yield of the laser diode of the nitride semiconductor, compared with the production yield of the conventional GaAs-based semiconductor laser diode.

(Structure of the Nitride Semiconductor Freestanding Substrate of this Embodiment)

Therefore, according to this embodiment, it is possible to realize the nitride semiconductor freestanding substrate wherein the dislocation density on the substrate surface is 4×10⁶/cm² or less, and there is an in-surface variation of the directions of the crystal axes along the substrate surface at each point in the surface of the substrate, with the variation of the directions of the crystal axes along the substrate surface set to be within a range of ±0.2° or less. Thus, it is found that improvement of the production yield of the laser diode and improvement of the device characteristics can be realized by defining a distribution (variation) of the directions of the crystal axes of the nitride semiconductor freestanding substrate.

As will be described in detail hereinafter, inventors of the present invention found that the in-surface variation of the directions of the crystal axes along the substrate surface can be set to be in a range of ±0.2° or less by using a new growth method for uniformizing growth conditions in the surface of the substrate. By the new growth method for uniformizing the growth conditions in the surface of the substrate, a film thickness distribution of the nitride semiconductor layer can be set to be ±2% or less in as-grown state, and the nitride semiconductor freestanding substrate, with directions of the crystal axes along the substrate surface more aligned than conventional, can be obtained.

In addition, by using a general method of lowering the density of crystal nuclei formed at a primary stage of a growth, the dislocation density in the substrate surface can be set to be 4×10⁶/cm² or less. It is found that the in-surface variation of the directions of the crystal axes along the vertical line on the substrate surface at each point in the surface of the substrate can be suppressed to a lower value of about ±0.2° or less by setting the dislocation density in the surface of the substrate to be 4×10⁶/cm² or less.

Here, the “freestanding substrate” means the substrate capable of not only maintaining the self-shape but also having strength not generating inconvenience in handling. In order to have such a strength, the thickness of the freestanding substrate is preferably set to be 200 μm or more. Further, the thickness of the freestanding substrate is preferably set to be 1 mm or less, in consideration of facilitating the cleavage after element formation. If the freestanding substrate is too thick, the cleavage is difficult, and irregularities are generated on the cleavage surface. As a result, when applied to, for example, the semiconductor laser, etc, deterioration of the device characteristics due to loss of reflection is problematic.

The diameter of the freestanding substrate is preferably set to be 2 inches or more. The diameter of the freestanding substrate depends on the diameter of a base substrate (substrate for growth) used in manufacture, and by using, for example, a sapphire substrate having diameter of 6 inches as the base substrate, the freestanding substrate having diameter of 6 inches can be obtained.

Further, in the measurement of the directions of the crystal axes in the nitride semiconductor freestanding substrate, the directions of the crystal axes along the substrate surface at each point in the surface of the substrate, and the directions of the crystal axes along the vertical line on the substrate surface at each point in the surface of the substrate, were obtained by X-ray diffraction of the substrate surface.

### (Relation Between the Dislocation Density (Defect Density) and the Variation of the Directions of the Crystal Axes)

In the manufacture of the nitride semiconductor freestanding substrate, as a general method for obtaining the substrate having low defect density, the following method is adopted. Namely, at the primary stage when the nitride semiconductor layer, being the freestanding substrate, grows on the substrate, being the base, the density of the crystal nuclei generated initially on the base substrate, is set to be low, and each nucleus is grown large so as to be fused with each other. This is based on the concept that by reducing these fused parts, generation of the crystal defects can be suppressed, because the crystal defects are easily generated at the fused parts between nuclei.

As a method of reducing nucleus density at the primary stage, there are methods such as a method of reducing the nucleus density by lowering the density of an opening part of an insulating mask, and a method of reducing the density of the nuclei formed at the primary stage by lowering an adhesion coefficient of raw materials, with respect to the substrate surface by lowering a degree of supersaturation of the raw materials on the substrate surface at the primary stage of the growth.

A problem of the method of obtaining the substrate having low defect density by reducing the nucleus density, is that, as shown in FIG. 1, regarding the crystal nuclei generated at the primary stage of the growth, the directions of the crystal axes along the substrate surface are not necessarily mutually aligned.

Therefore, as described above, when the freestanding substrate is manufactured based on low nucleus density, the obtained freestanding substrate with low defect density becomes a crystal aggregate of a macro-size, with the directions of the crystal axes along the substrate surface mutually deviated in each crystal nucleus.

For example, in a case of the GaN freestanding substrate having 3 inch diameter, with its surface formed into C-face, the variation of the crystal axes along the substrate surface is within a range of ±0.2° or less, if the dislocation density of the substrate surface is about 5×10⁶/cm² or more. However, in a case of the substrate with low defect density, with the dislocation density of the substrate surface set to be 4×10⁶/cm² or less in accordance with the aforementioned general method, the variation of the directions of the crystal axes along the substrate surface is deteriorated to ±0.5° or more (see FIG. 4 of an example as will be described later).

Meanwhile, if the nucleus density at the primary stage of the growth is lowered, the variation of the directions of the crystal axes is reduced, in a direction vertical to the surface of the freestanding substrate obtained finally. When the nitride semiconductor freestanding substrate is grown, the dislocation density is gradually reduced with a progress of the growth. Therefore, in the freestanding substrate obtained finally, the dislocation density is different between the front side and the backside. Different dislocation density means different numbers of atoms that exist on the front side and the backside of the substrate, and by this different numbers of atoms, a crystal face along the substrate surface is warped. By this warpage of the freestanding substrate, the variation is generated in the directions of specific crystal axes approximately vertical to the substrate surface (see FIG. 1).

When the nucleus density at the primary stage of the growth is low, less dislocation is generated by mutual fusion of the nuclei as described above, and therefore a difference of the dislocation density between the front side and the backside of the substrate is small, and the variation in the directions of the crystal axes approximately vertical to the surface is reduced.

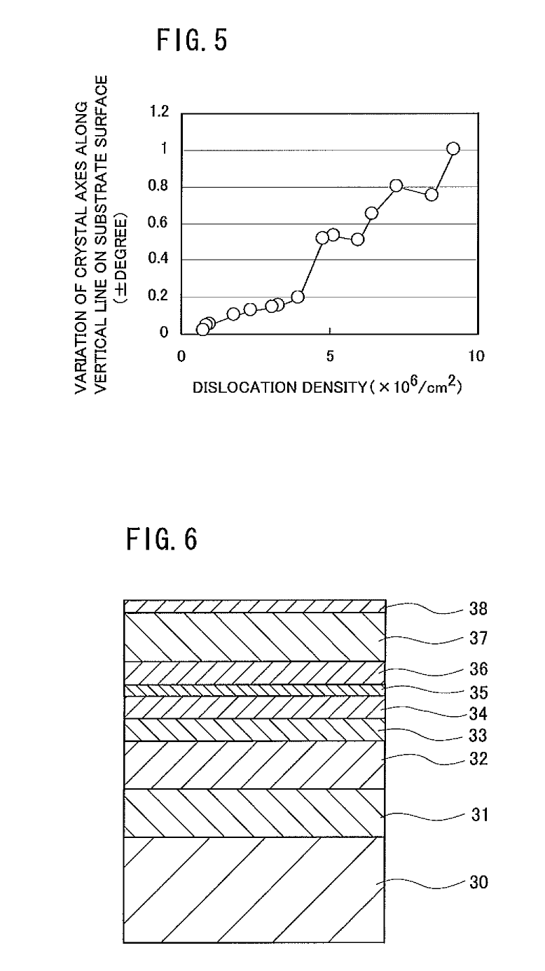

If a specific numeric value is given as an example, for example, when the dislocation density of the substrate surface is about 5×10⁶/cm² or more, in the GaN freestanding substrate having a diameter of 3 inches, the variation of the directions of the crystal axes approximately vertical to the substrate surface is ±0.5° or more. Meanwhile, when the dislocation density of the substrate surface is 4×10⁶/cm² or less, the variation of the directions of the crystal axes approximately vertical to the substrate surface can be suppressed to a lower value of ±0.2° or less (see an example of FIG. 5 as will be described later).

In conclusion, in the nitride semiconductor freestanding substrate, when the initial nucleus density is increased, dislocation becomes high, and in this case, the variation of the directions of the crystal axes in the direction approximately parallel to the substrate surface along the substrate surface is reduced. However, the variation of the crystal axes in the direction approximately vertical to the substrate surface along the vertical line on the substrate surface is increased. Meanwhile, when the initial nucleus density is reduced, the dislocation becomes low, and the variation of the directions of the crystal axes in the direction approximately parallel to the substrate surface is increased, and the variation of the directions of the crystal axes in the direction approximately vertical to the substrate surface is reduced. The present situation is that it is difficult to obtain the nitride semiconductor freestanding substrate, with the directions of the crystal axes aligned respectively in both directions of the direction approximately parallel to the substrate surface and the direction approximately vertical to the substrate surface in the surface of the substrate, even if the initial nucleus density is increased or reduced.

### (Reducing Method of the Variation of the Crystal Axes)

Therefore, after a strenuous effort by the inventors of the present invention for improving the variation of the directions of the crystal axes of the nitride semiconductor freestanding substrate, it is found that the nitride semiconductor freestanding substrate can be manufactured, with the directions of the crystal axes aligned respectively in both directions of the direction along the substrate surface and the direction along the vertical line on the substrate surface, by suppressing the variation low in the directions of the crystal axes along the vertical line on the substrate surface by using the method of lowering the density of the nuclei formed at the primary stage of the growth, and by suppressing the variation of the crystal axes along the substrate surface of the nuclei at the primary stage of the growth, by using a new growth method for uniformizing growth conditions in the surface of the substrate.

As will be described specifically hereinafter, an orientation deviation of the crystal nuclei at the primary stage of the growth is caused by the variation (non-uniformity) of the growth conditions in the surface of the substrate at the primary stage of the growth of the freestanding substrate, and this is the cause of the variation of the directions of the crystal axes along the substrate surface of the nitride semiconductor freestanding substrate finally obtained. Therefore, the new growth method with less variation of the growth conditions in the surface of the substrate is introduced.

### (The Variation of the Directions of the Crystal Axes Along the Substrate Surface and the Growth Conditions)

The growth of the nitride semiconductor freestanding substrate, for example, the GaN freestanding substrate at the primary stage is the growth of GaN on Ti in the aforementioned VAS method, and in the DEEP method, the growth is the growth of GaN on GaAs, and each growth is the growth on the substrate made of heterogeneous materials. When the material is different, distance between atoms constituting each material is originally different, and therefore it is known that there is a case that each material is joined in a form that the orientation of the crystal axes is deviated in a joint surface, so as to minimize an energy required for forming a joint when these heterogeneous materials are joined. The growth of a C-face GaN layer on sapphire C-face can be given as a typical example, and in this case, the GaN layer, being a growing layer, grows by carrying out rotation of 30° with respect to sapphire on the joint surface with sapphire.

This time, as a result of examining in detail the case of growing the GaN layer on the base of the GaAs and Ti, it is found that a small rotation of 1° or less of the crystal axis is generated, which is not a large rotation as in the case of the GaN layer on sapphire. Further, it is clarified that a small rotational angle of the crystal axes is varied depending on the growth condition of a crystal at the primary stage of the growth. Although a mechanism of determining the rotational angle is not clarified, it is estimated that when the condition at the primary stage of the growth is different, a state of rearrangement of atoms on the Ti surface and GaAs surface, being the base, is changed under an influence of the growth condition, thereby generating the difference of the rotational angle.

When the growth condition is different in the surface of the substrate, the nuclei with deviated crystal orientation are generated at each place in the surface of the substrate at the primary stage of the growth.

When the dislocation density of the freestanding substrate is great (typically when it is larger than 4×10⁶/cm²), namely, when the nucleus density at the primary stage of the growth is great, the adjacent nuclei are fused with each other when they are small. When the nucleus is small, energy for rotating/deforming the nucleus is also small, and therefore each nucleus is easily rotated/deformed in a prescribed direction when the nuclei are fused with each other, thus aligning the crystal orientation of each nucleus. Therefore, the variation of the crystal axes in a direction along the substrate surface at a stage of a continuous film becomes small.

There is no report of the variation of the crystal axes, regarding the GaN layer formed on the sapphire substrate by the MOVPE method (metal-organic vapor phase epitaxy method) used in general conventionally. This is because the dislocation density of the obtained GaN layer is great such as 1×10⁸/cm² to 1×10¹⁰/cm², and the crystal orientation is easily aligned when small nuclei are fused with each other as described above, to thereby make the variation of the crystal axes negligibly small.

Meanwhile, in a case of the freestanding substrate with less nucleus density at the primary stage of the growth and low dislocation (typically 4×10⁶/cm² or less), the nuclei with deviated crystal orientation are fused with each other after being grown greater. Since great energy is required for rotating a great nucleus, such a rotation is hardly generated, and the freestanding substrate having variation in the directions of the crystal axes along the substrate surface is formed.

When the nitride semiconductor freestanding substrate is manufactured by the aforementioned VAS method and DEEP method, in either one of the methods, the HVPE method (Hydride Vapor Phase Epitaxy Method) is used for growing a thick GaN layer at a high rate (for examples, at a growing rate of 50 μm/hr or more). Generally when compared with the MOVPE method used in epitaxial growth of a device structure, uniformity of the film thickness distribution is deteriorated in a case of using the HVPE method. Specifically, in a case of using the MOVPE method, typical film thickness distribution is about ±2% when the substrate has diameter of 3 inches. Meanwhile, in a case of using the HVPE method, typical film thickness distribution is about ± several 10%. To grow the nitride semiconductor freestanding substrate by using the HVPE method, in which the film thickness uniformity is deteriorated, is in other words, to grow the nitride semiconductor freestanding substrate, with conditions varied from place to place in the surface of the substrate, resulting in generation of the variation in the crystal axis orientation along the substrate surface.

### (A Manufacturing Method of the Nitride Semiconductor Freestanding Substrate)

For the reason described above, it appears that improvement of the film thickness uniformity by the HVPE method is effective for suppressing the variation of the crystal axis orientation along the substrate surface of the nitride semiconductor freestanding substrate, and the inventors of the present invention examine various methods for improving the film thickness uniformity of the HVPE method. In this process, it is found that by setting a distance from a jet hole of the source gas to the substrate to be 50 cm or more, and by setting a gas flow speed in a crystal growing area to be 1 m/s or more, the film thickness distribution can be tremendously improved.

FIG. 2 shows a schematic vertical view of an HVPE apparatus used in this embodiment. As shown in the figure, this HVPE apparatus includes a lateral reaction furnace, in which a cylindrical reaction tube 10 made of silica, with both ends closed, is horizontally disposed. NH₃ gas inlet tube 14 for introducing gas containing NH₃ gas into the reaction tube 10, and HCl gas inlet tube 15 for introducing gas containing HCl gas into the reaction tube 10 are provided horizontally, so as to pass through a side wall of one end side of the reaction tube 10. NH₃ gas is supplied to the NH₃ gas inlet tube 14 from a supply line on the upstream side of the reaction tube 10, together with carrier gas N₂ and H₂, and also HCl gas is supplied to the HCl gas inlet tube 15 from the supply line on the upstream side of the reaction tube 10, together with carrier gas N₂ and H₂.

The HCl gas inlet tube 15 is connected to a container 16 for containing Ga. In the container 16, reaction occurs between the HCl gas introduced from the HCl gas inlet tube 15 and Ga melt 17 in the container 16, to thereby generate GaCl gas. The gas containing the generated GaCl gas is led out from the GaCl gas outlet tube 18 connected to the container 16. GaCl gas outlet tube 18 is disposed in parallel to outlet 14a side of the NH₃ gas inlet tube 14, and positions on a vertical line of outlet (GaCl gas jet hole) 18a of the GaCl gas outlet tube 18 and outlet (NH₃ gas jet hole) 14a of the NH₃ gas inlet tube 14 coincide with each other.

A substrate holder 11 for holding a substrate for growth 5, being a starting substrate (base substrate) for growing the GaN layer, is provided so as to be opposed to the outlet 18a of the GaCl gas outlet tube 18 and the outlet 14a of the NH₃ gas inlet tube 14. The substrate for growth 5 is held by the substrate holder 11, with its surface (growth surface) being vertical, and the gas jetted from the outlet 14a of the NH₃ gas inlet tube 14 and the outlet 18a of the GaCl gas outlet tube 18 is blown against the surface of the substrate for growth 5. The substrate holder 11 is supported by a support shaft 12 provided horizontally so as to pass through the side wall of the end portion of the reaction tube 10 on the opposite side of the NH₃ gas inlet tube 14. The support shaft 12 is constituted rotatably around its shaft, and by the rotation of the support shaft 12, the substrate for growth 5 installed on the substrate holder 11 can be rotated around its central axis. Further, the support shaft 12 can be moved horizontally, so that distance “d” from the substrate for growth 5 installed on the substrate holder 11 to the outlet 18a of the GaCl gas outlet tube 18 and the outlet 14a of the NH₃ gas inlet tube 14 can be varied. The distance “d” can be varied in a range of 5 to 100 cm. An exhaust tube 19 is provided on the side wall of the end portion of the reaction tube 10 through which the support shaft 12 is passed, and the gas in the reaction tube 10 is exhausted from the exhaust tube 19. An exhaust system (not shown) including a vacuum pump is connected to the exhaust tube 19.

A raw material part heater 20 and a growth part heater 21 are provided on the outer peripheral part of the reaction tube 10. The raw material part heater 20 is provided on the outer periphery of the container 16 and its peripheral part, and the growth part heater 21 is provided on the outer periphery of the substrate holder 11 and its peripheral part. Thermocouple 13 for measuring a temperature of the substrate for growth 5 is provided in the support shaft 12.

The NH₃ gas jetted from the outlet 14a of the NH₃ gas inlet tube 14 and the GaCl gas jetted from the outlet 18a of the GaCl gas outlet tube 18 are flown to the substrate for growth 5 installed on the substrate holder 11 while mixing with each other, and reaction occurs between the NH₃ gas and the GaCl gas on the surface of the substrate for growth 5, to thereby grow the GaN crystal.

In a conventional HVPE method, the distance “d” from jet holes 14a, 18a of the source gas to the substrate for growth 5 is about 10 cm and is short. Therefore, the source gas, in which mixing of III-group source gas and V-group source gas are non-uniform, reaches the surface of the substrate for growth 5, and this is a factor of non-uniformity of the film thickness of the GaN layer. In addition, in the conventional HVPE method, the gas flow speed of the source gas on the substrate for growth 5, being an area where the GaN layer grows, is about several cm/s and is slow. Therefore, gas flow is disturbed under an influence of a level difference of a jig, etc, inside of the apparatus and an adhesion matter produced after growth, and this is also a factor of a large film thickness distribution.

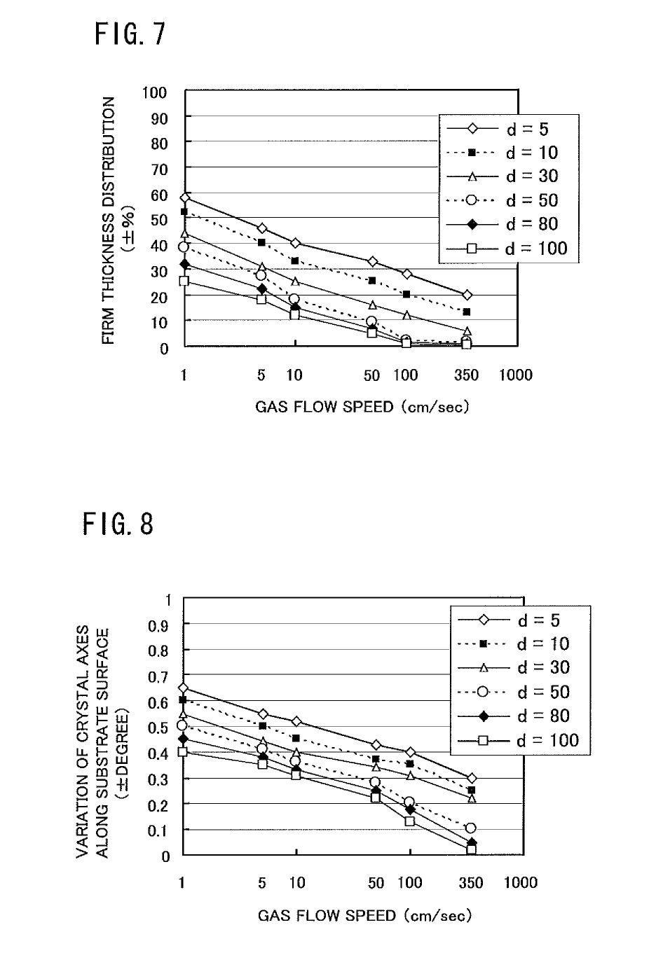

The effect of the improvement by uniformizing the growth conditions in the surface of the substrate is as follows. If expressed by a specific numerical value, in a case of the conventional growth method in which the distance “d” from the source gas jet holes 14a, 18a to the substrate for growth 5 is set to be 10 cm and the gas flow speed is set to be 5 cm/s, the film thickness distribution in the surface of the substrate for growth 5 having 3 inch diameter is ±40%. Meanwhile, in a case of the growth method according to the embodiment in which the distance “d” from the source gas jet holes 14a, 18a to the substrate for growth 5 is set to be 50 cm and the gas flow speed is set to be 1 m/s, the film thickness distribution is greatly improved to ±2% (see FIG. 7 of an example as will be described later).

Note that the gas flow speed described in this specification is a value obtained by correcting a value measured by flowing nitrogen gas equivalent to a total gas amount used for growth at a room temperature, and using an air speedometer at point R on the end portion of the substrate holder 11 of FIG. 2 having a size of inches, in consideration of a volume expansion coefficient at a growth temperature. Namely, it can be considered that when the gas flow speed at the room temperature (300K) is 0.3 m/s, the gas flow speed at the growth temperature such as 1060° C.=1333K is 1.33 m/s, namely 1333/300=4.44 times.

In a circular freestanding substrate having 2 to 6 inch diameter, when such a new growth method aiming at uniformization of the growth conditions is applied to the manufacture of the GaN freestanding substrate by the VAS method, it is possible to succeed in improvement of the variation of the directions of the crystal axes to ±0.2° or less in a case of using the growth method of this embodiment. Meanwhile, in the conventional growth method, the variation of the directions of the crystal axes along the substrate surface is ±0.5° or more when the dislocation density is 4×10⁶/cm² or less (see FIG. 8 of an example as will be described later). Further, in these GaN substrates, the variation of the directions of the crystal axes along the vertical line on the substrate surface is also ±0.2° or less. Therefore, it is possible to obtain the GaN freestanding substrate in which the directions of the crystal axes are more aligned than conventional in both directions of the direction approximately parallel to the substrate surface and the direction approximately vertical to the substrate surface.

Moreover, when the laser diode is manufactured by forming and laminating the epitaxial layer of a laser diode structure on the GaN freestanding substrate, by using the GaN freestanding substrate with directions of the crystal axes aligned, high production yield such as 50% or more can be obtained.

The present invention is also effective not only to the GaN freestanding substrate having C-face of a wurtzite structure, but also to the GaN freestanding substrate having M-face, A-face, or the high index face between these faces (for example, (11-22) face, (12-32) face), or the inclined surface (vicinal surface) inclined from these faces in a range of 5° or less, as the surface. Further, the present invention is also similarly effective to the GaN freestanding substrate having a zinc blende structure, being a cubic crystal structure. Namely, the present invention is applied to the GaN freestanding substrate of the zinc blende structure having (001) face, (111) A-face, (111) B-face, or the high index face between these faces (for example, (113) A-face, (114) B-face), or the inclined surface (vicinal surface) inclined from these faces in a range of 5° or less as the surface, and also similarly effective to the GaN freestanding substrate of a wurtzite structure. In addition, the present invention is effective not only to the GaN freestanding substrate but also to the nitride semiconductor freestanding substrate such as AlN, InN, AlGaN, InAlGaN, BAlN, BInAlGaN.

In the present invention, the nitride semiconductor freestanding substrate may be manufactured by using any kind of a growth apparatus, provided that the uniformization of the growth conditions in the surface of the substrate is achieved. The horizontal type HVPE apparatus of FIG. 2 has a structure of vertically supporting the substrate for growth 5. However, a horizontal type HVPE apparatus for horizontally supporting the substrate for growth 5 may also be used. Further, it is a matter of course that the nitride semiconductor freestanding substrate can be manufactured by using a vertical type HVPE apparatus for vertically flowing the source gas, or by using the MOVPE apparatus.

### EXAMPLES

Next, examples of the present invention will be described.

### First Example

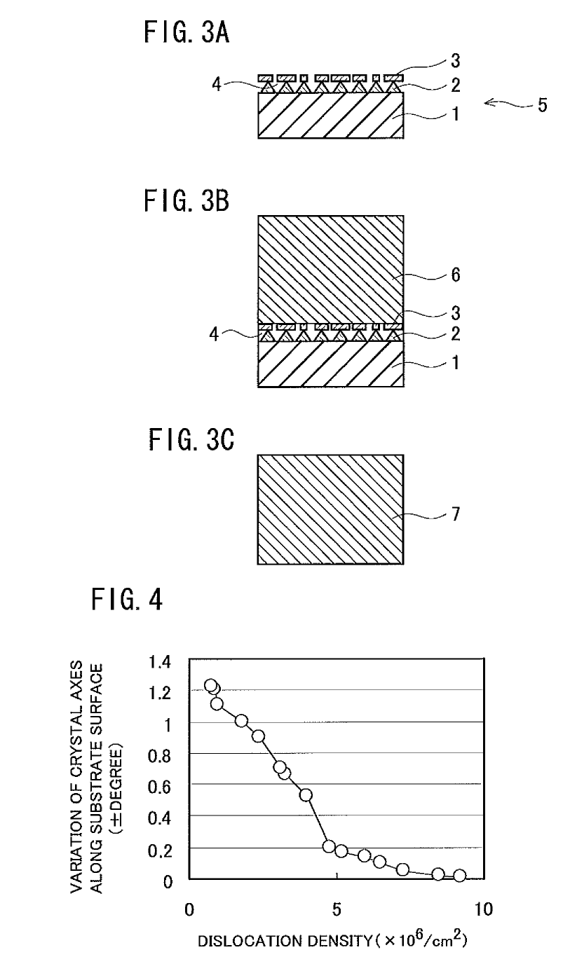

In a first example, the GaN freestanding substrate was manufactured by using the VAS method. A manufacturing step of the GaN freestanding substrate of the first example is shown in FIG. 3A to FIG. 3C.

First, a GaN thin film was grown on the sapphire substrate 1 by the MOCVD method, and a Ti film was formed on this GaN thin film as a metal film by a vapor deposition method, and thereafter heat treatment was applied thereto. By this heat treatment, the substrate for growth (starting substrate) 5 was formed, with the GaN thin film on a sapphire substrate 1 set as a void forming GaN layer 2 having a plurality of voids 4, and the Ti film set as a net-like structure TiN film 3 (FIG. 3A).

Next, a GaN thick film 6 was grown on the substrate for growth 5, to a thickness of 300 μm or more (FIG. 3B). The HVPE apparatus shown in FIG. 2 was used for growing this GaN thick film 6. The substrate was taken out from the reaction furnace after growing the GaN thick film 6, and the GaN thick film 6 was mechanically separated, with the TiN film 3 as a boundary, to thereby obtain a GaN substrate 7 by polishing front/rear surfaces of the separated GaN thick film (FIG. 3C).

In the example (including a comparative example) using the HVPE apparatus of FIG. 2, the temperature of the raw material part heater 20 was maintained in a range of 800 to 950° C., and the temperature of the growth part heater 21 was maintained in a range of 1000 to 1200° C., at the stage of the growth of the GaN thick film 6. Further, the substrate temperature was measured on the backside of the substrate holder 11 by the thermocouple 13, and the temperature of the substrate for growth 5 was set in a range of 1050 to 1100° C. Moreover, the pressure in the reaction tube 10 was set to be 1 to 200 kPa, HCl flow rate was set to be 1 sccm (standard cc/min) to 10 slm (standard liter/min), NH₃ flow rate was set to be 1 sccm to 20 slm, H₂ flow rate was set to be 1 slm to 100 slm, and N₂ flow rate was set to be 1 slm to 100 slm.

As a comparative example, in the HVPE apparatus of FIG. 2, the distance “d” from the gas jet holes 14a, 18a to the substrate for growth 5 was set to be 10 cm, and the gas flow speed was set to be 5 cm/s, to thereby manufacture a C-face GaN freestanding substrate having a wurtzite structure. In the comparative example, the GaCl flow rate and the NH₃ flow rate at the primary stage of the growth were varied, and initial nucleus density was controlled by varying the degree of the supersaturation of the source gas on the surface of the substrate for growth 5, to thereby manufacture various GaN freestanding substrates with different dislocation density.

FIG. 4 shows a relation between the dislocation density of the obtained GaN freestanding substrate of the comparative example, and the in-surface variation of the directions of the crystal axes along the substrate surface. Also, FIG. 5 shows a relation between the dislocation density of the obtained GaN freestanding substrate, and the in-surface variation of the directions of the crystal axes along the vertical line on substrate surface.

When the dislocation density was greater than about 5×10⁶/cm², the variation of the directions of the crystal axes along the substrate surface was ±0.2° or less (FIG. 4), and the variation of the directions of the crystal axes along the vertical line on the substrate surface was ±0.5° or more (FIG. 5). Also, when the dislocation density was 4×10⁶/cm² or less, the variation of the directions of the crystal axes along the substrate surface was ±0.5° or more (FIG. 4), and the variation of the directions of the crystal axes along the vertical line on the substrate surface was ±0.2° or less (FIG. 5).

By using the GaN freestanding substrate of the comparative example, laser diode of bluish-purple shown respectively in FIG. 6 was manufactured. Namely, n-type GaN layer 31, n-type AlGaN layer 32, n-type GaN optical guide layer 33, and a triple quantum well layer 34 of InGaN/GaN structure, p-type AlGaN layer 35, p-type GaN optical guide layer 36, p-type AlGaN/GaN superlattice layer 37, p-type GaN layer 38 were sequentially laminated and formed on the GaN freestanding substrate 30 by the MOPVE method.

The production yield of the laser diode manufactured by using each GaN freestanding substrate of the comparative example was about 7% respectively. This is because, as described above, the variation of the crystal axes in the direction approximately parallel or approximately vertical to the substrate surface is great, and therefore parallelism of the resonator formed by the cleavage surface is poor.

Next, as the example and the comparative example, in the HVPE apparatus of FIG. 2, the distance “d” from the gas jet holes 14a, 18a to the substrate for growth 5 was varied between 5 to 100 cm, and the gas flow speed in the crystal growth area was varied in a range of 1 to 350 cm/sec, to thereby manufacture the C-face GaN substrate having a diameter of 3 inches and having a wurtzite structure, with dislocation density set to be 4×10⁶/cm². The manufactured C-face GaN substrate has a uniform dislocation density in the surface of the substrate. Here, the value of the dislocation density is the value of an average dislocation density in the surface of the substrate.

FIG. 7 shows the relation among the distance “d” from the gas jet hole to the substrate, the gas flow speed, and the film thickness distribution in the surface of the substrate. Also, FIG. 8 shows the relation among the distance “d” from the gas jet hole to the substrate, the gas flow speed, and the variation of the directions of the crystal axes along the substrate surface.

As shown in FIG. 7, in the freestanding substrate of the comparative example with the distance “d” from the gas jet hole to the substrate set to be 10 cm and the gas flow speed set to be 5 cm/s, the film thickness distribution was about ±40%. However, in the freestanding substrate of the example with the distance “d” expanded to 50 cm and further the gas flow speed set to be 1 m/sec or more, the film thickness distribution could be set to ±2% or less.

Also, as shown in FIG. 8, in the freestanding substrate of the comparative example with the distance “d” from the gas jet hole to the substrate set to be 10 cm and the gas flow speed set to be 5 cm/s, the variation of the crystal axes along the substrate surface was ±0.5°. Meanwhile, in the freestanding substrate of the example with the distance “d” from the gas jet hole to the substrate expanded to 50 cm and further the gas flow speed set be 1 m/sec or more, the variation of the crystal axes along the substrate surface was ±0.2° or less.

As described above, from FIG. 7 and FIG. 8, it is found that by expanding the distance “d” from the raw material jet hole to the substrate and further by increasing the gas flow speed, the film thickness distribution is improved, and the variation of the directions of the crystal axes along the substrate surface is reduced. As described above, to make a small film thickness distribution is to uniformize the growth conditions at each point on the substrate surface, and it can be considered that this is a result of more aligned directions of a plurality of nuclei formed at the primary stage of the growth as a result, than conventional in the same direction.

In addition, as an example, in the 3 inch GaN substrate with dislocation density set to be 4×10⁶/cm², manufactured with the distance “d” from the raw material jet hole to the substrate set to be 50 cm and the gas flow speed set to be 1 m/sec, there was a variation of ±0.2° or less in the directions of the crystal axes in both directions approximately parallel to and approximately vertical to the substrate surface, over the whole surface of the substrate.

Similarly, the C-face GaN freestanding substrate having a diameter of 2 to 6 inches, with the distance “d” from the raw material jet hole to the substrate set to be 50 cm to 100 cm and the gas flow speed varied in a range of 1 m/sec to 10 m/sec, and the dislocation density of the surface set to be 4×10⁶/cm² to 2×10⁵/cm², and the GaN freestanding substrate having a surface slightly inclined by 5° or less from the C-face in A-axial direction, M-axial direction, or in a direction of intermediate of them, were formed. In each of these GaN freestanding substrates also, it is possible to succeed in making the variation of ±0.2° or less of the directions of the crystal axes in both directions approximately parallel and approximately vertical to the substrate surface, over the whole surface of the substrate. Further, when the distance “d” from the raw material jet hole to the substrate was set to be 100 cm, and the gas flow speed was set to be 350 cm/s, the variation of the directions of the crystal axes in both directions approximately parallel, and approximately vertical to the substrate surface could be set to ±0.02° or less over the whole surface of the substrate.

When the laser diode of bluish-purple shown in FIG. 6 was manufactured similarly to the aforementioned comparative example by using the GaN substrate of the example with more aligned directions of the crystal axes than conventional, the production yield was about 60%. Therefore, the production yield was tremendously improved compared with the production yield of about 7% in the comparative example.

Thus, according to this example, a maximum absolute value of the in-surface variation of the directions of the crystal axes along the substrate surface could be controlled in a range of 0.02° or more and 0.2° or less, and a maximum absolute value of the in-surface variation of the directions of the crystal axes along the vertical line on the substrate surface could be controlled in a range of 0.02° or more and 0.2° or less.

### Second Example

In the first example, the GaN freestanding substrate of a wurtzite structure was manufactured by using various substrates for growth 5 manufactured from the sapphire substrate 1 with different surface orientation. The obtained GaN freestanding substrate has a diameter of 2 to 6 inches, dislocation density of 4×10⁶/cm² to 2×10⁵/cm², with its surface formed into C-face, M-face, A-face and the high index face of intermediate of them, or the face slightly inclined by 5° or less from these faces. In the same way as the first example, when the distance “d” from the gas jet hole to the substrate was set to be 50 cm or more and the gas flow speed was set to be 1 m/s or more, the variation of the directions of the crystal axes in both directions approximately parallel and approximately vertical to the substrate surface was ±0.2° or less in the surface of the substrate. Further, the production yield of the element, with a laser diode structure grown on these freestanding substrates, was about 60% similarly to the first example, and tremendously improved compared with 7% of the comparative example.

### Third Example

In the first example, the GaN freestanding substrate of a zinc blende structure was manufactured by using various GaAs substrates with different face orientation, instead of the substrate for growth using the sapphire substrate. In this third example, the VAS method was not used and the GaN layer was grown directly on the GaAs substrate, and after growth of the GaN layer, the GaAs substrate was subjected to etching, to thereby obtain the GaN freestanding substrate.

The obtained GaN freestanding substrate of a zinc blende structure had a diameter of 2 to 6 inches and dislocation density of 4×10⁶/cm² to 2×10⁵/cm², and which was a substrate, with its surface formed into (001) face, (111) A-face, (111) B-face, and the high index face between these faces, and the face slightly inclined from these crystal faces in a range of 5° or less. In this case also, in the same way as the example 1, it was possible to succeed in setting the in-surface variation of the directions of the crystal axes in both directions approximately parallel and approximately vertical to the substrate surface, to be in a range of ±0.2° or less, when the gas flow speed was set to be 1 m/s or more. When a laser structure shown in FIG. 6 was grown on these freestanding substrates, the production yield was about 60% in the same way as the example 1, and was tremendously improved compared with 7% of the comparative example. Note that laser grown on the GaN substrate of a zinc blende structure oscillates in a range of blue color to green color, unlike the aforementioned substrate of a wurtzite structure. This is because band gap is smaller in GaN of a zinc blende structure than that in GaN of a wurtzite structure, and therefore light emission occurs in a longer wavelength.

### The Other Examples

The freestanding substrate was manufactured in the same way as first to third examples. However, not the GaN freestanding substrate, but the nitride semiconductor freestanding substrate made of AlN, InN, AlGaN, InAlGaN, BAlN, BInAlGaN was manufactured. Excellent results similar to those of the first to third examples could be obtained in any one of these freestanding substrates.

In the same way as the first to third examples, the freestanding substrate was manufactured, and when the MOVPE method was used as the growth method of the GaN layer, becoming the freestanding substrate, excellent results similar to those of the first to third examples could be obtained.

In the same way as the first to third examples, the freestanding substrate was manufactured, and a molecular beam epitaxy (MBE) method, a liquid phase growth method using Na flux, and an ammonothermal method were used as growth methods of the GaN layer, becoming the freestanding substrate. These growth methods are not the methods of growing the GaN layer by flowing gas like the HVPE method and the MOVPE method. However, in the same way as the HVPE method and the MOVPE method, by setting in-surface distribution of the growing rate to be in a range of ±2% or less, excellent results similar to those of the first to third examples could be obtained in a case of any one of these growing methods also.

Note that in some cases, a substrate having a specific surface difficult to grow is required, depending on the purpose of use of the nitride semiconductor freestanding substrate. In this case, a thick freestanding substrate is grown, with C-face easy to grow relatively as a surface, and by obliquely or vertically cutting it, the freestanding substrate having such a specific surface can be obtained. In the freestanding substrate manufactured by a conventional method, as described above, the crystal axis in one direction orthogonal to at least C-face is extremely curved, and therefore even if the substrate having such a specific surface is cut out, its crystal axis is also curved.

However, if the freestanding substrate with aligned directions of the crystal axes is used, the freestanding substrate having such a specific surface can also be manufactured in a form of aligned crystal axes.

1. A nitride semiconductor freestanding substrate, with a dislocation density set to be 4×10⁶/cm² or less in a surface of the nitride semiconductor freestanding substrate, having an in-surface variation of directions of crystal axes along the substrate surface at each point on the substrate surface, with this variation of the directions of the crystal axes along the substrate surface set to be in a range of ±0.2° or less.

2. The nitride semiconductor freestanding substrate according to claim 1, having an in-surface variation of the directions of the crystal axes along a vertical line on the substrate surface at each point in the surface of the substrate, with this variation of the directions of the crystal axes along the vertical line on the substrate surface set to be in the range of ±0.2° or less.

3. The nitride semiconductor freestanding substrate according to claim 1, wherein the nitride semiconductor freestanding substrate has a wurtzite structure, and the substrate surface is C-face.

4. The nitride semiconductor freestanding substrate according to claim 1, wherein the nitride semiconductor freestanding substrate has a wurtzite structure, and the substrate surface is an inclined surface inclined from C-face in a range of 5° or less.

5. The nitride semiconductor freestanding substrate according to claim 1, wherein the nitride semiconductor freestanding substrate has a wurtzite structure, and the substrate surface is M-face.

6. The nitride semiconductor freestanding substrate according to claim 1, wherein the nitride semiconductor freestanding substrate has a wurtzite structure, and the substrate surface is an inclined surface inclined from M-face in a range of 5° or less.

7. The nitride semiconductor freestanding substrate according to claim 1, wherein the nitride semiconductor freestanding substrate has a wurtzite structure, and the substrate surface is A-face.

8. The nitride semiconductor freestanding substrate according to claim 1, wherein the nitride semiconductor freestanding substrate has a wurtzite structure, and the substrate surface is an inclined surface inclined from A-face in a range of 5° or less.

9. The nitride semiconductor freestanding substrate according to claim 1, wherein the nitride semiconductor freestanding substrate has a wurtzite structure, and the substrate surface is a high index face between two faces of any one of C-face, M-face, and A-face.

10. The nitride semiconductor freestanding substrate according to claim 1, wherein the nitride semiconductor freestanding substrate has a zinc blende structure, and the substrate surface is (001) face.

11. The nitride semiconductor freestanding substrate according to claim 1, wherein the nitride semiconductor freestanding substrate has a zinc blende structure, and the substrate surface is an inclined surface inclined from (001) face in a range of 5° or less.

12. The nitride semiconductor freestanding substrate according to claim 1, wherein the nitride semiconductor freestanding substrate has a zinc blende structure, and the substrate surface is (111) A-face.

13. The nitride semiconductor freestanding substrate according to claim 1, wherein the nitride semiconductor freestanding substrate is has a zinc blende structure, and the substrate surface is an inclined surface inclined from (111) A-face in a range of 5° or less.

14. The nitride semiconductor freestanding substrate according to claim 1, wherein the nitride semiconductor freestanding substrate has a zinc blende structure, and the substrate surface is (111) B-face.

15. The nitride semiconductor freestanding substrate according to claim 1, wherein the nitride semiconductor freestanding substrate has a zinc blende structure, and the substrate surface is an inclined surface inclined from (111) B-face in a range of 5° or less.

16. The nitride semiconductor freestanding substrate according to claim 1, wherein the nitride semiconductor freestanding substrate has a zinc blende structure, and the substrate surface is a high index face between two faces of any one of (001) face, (111) A-face, and (111) B-face.

17. The nitride semiconductor freestanding substrate according to claim 1, wherein the nitride semiconductor freestanding substrate has a film thickness distribution of ±2% or less in a state of as-grown.

18. A laser diode, having epitaxial layers of a laser diode structure laminated and formed on the nitride semiconductor freestanding substrate of claim 1.

19. A manufacturing method of a nitride semiconductor freestanding substrate, comprising the steps of:
growing a nitride semiconductor layer, becoming a nitride semiconductor freestanding substrate, on a substrate for growth by supplying gas containing source gas, using a hydride vapor phase epitaxy method or a metal-organic vapor phase epitaxy method; and
manufacturing the nitride semiconductor freestanding substrate from the nitride semiconductor layer obtained by removing the substrate for growth,
wherein in the step of growing the nitride semiconductor layer, a gas flow speed of the gas containing the source gas in an area for growing the nitride semiconductor layer on the substrate for growth is set to be 1 m/s or more, and a distance from a gas jet hole for jetting the gas containing the source gas for forming the nitride semiconductor layer, to the area for growing the nitride semiconductor layer is set to be 50 cm or more, to thereby grow the nitride semiconductor layer with a dislocation density set to be 4×10⁶/cm² or less.

20. The manufacturing method of the nitride semiconductor freestanding substrate according to claim 19, wherein in the step of growing the nitride semiconductor layer, a growing rate distribution in a surface of the nitride semiconductor layer is set to be ±2% or less.
